(19) United States
(12) Patent Application Publication
(10) Pub. No.: US 2026/0074145 A1
(43) Pub. Date: Mar. 12, 2026

(54) HEIGHT MEASUREMENTS USING FOCUS LINE

(71) Applicant: Carl Zeiss SMT GmbH, Oberkochen (DE)

(72) Inventors: Thomas KORB, Schwaebisch Gmuend (DE); Dmitry KLOCHKOV, Schwaebisch Gmuend (DE); Keumsil LEE, Half Moon Bay, CA (US)

(21) Appl. No.: 19/389,989

(22) Filed: Nov. 14, 2025

Related U.S. Application Data
(63) Continuation of application No. PCT/EP2024/063601, filed on May 16, 2024.
(60) Provisional application No. 63/504,301, filed on May 25, 2023.

(51) Int. Cl. H01J 37/305; G06T 7/00; H01J 37/22

(52) U.S. Cl. CPC H01J 37/3056; G06T 7/0004; H01J 37/222; G06T 2207/10061; G06T 2207/30148; H01J 2237/24578; H01J 2237/31749

(57) ABSTRACT

A method of operating a dual beam device comprises obtaining a milled sample having an assumed milled top surface shape which was obtained by milling the sample with a first ion beam of the dual beam device, and determining a plurality of height coordinates of the assumed milled top surface shape using a second beam of the dual beam device. The method also comprises determining at least one actual milling top surface shape for the milled sample based on the determined plurality of height coordinates, and determining a parameter of the sample based on the adapted milled top surface shape.

### CROSS-REFERENCE TO RELATED APPLICATIONS

The present application is a continuation of, and claims benefit under 35 USC 120 to, international application No. PCT/EP2024/063601, filed May 16, 2024, which claims benefit under 35 USC § 119(e) of U.S. Provisional Application No. 63/504,301, filed May 25, 2023. The entire disclosure of each of these applications is incorporated by reference herein.

### FIELD

The disclosure relates to a method for operating a dual-beam device. In some embodiments, techniques are disclosed that facilitate determining an actual milling top surface shape of a milled sample.

### BACKGROUND

Semiconductor structures are amongst the finest man-made structures and can suffer from different imperfections. Devices for quantitative 3D-metrology, defect-detection or defect review look for these imperfections. Fabricated semiconductor structures are generally based on prior knowledge. The semiconductor structures are manufactured from a sequence of layers being parallel to a substrate. For example, in a logic type sample, metal lines usually run parallel in metal layers or HAR (high aspect ratio) structures, and metal vias usually run perpendicular to the metal layers. The angle between metal lines in different layers is typically either 0° or 90°. On the other hand, for VNAND type structures their cross-sections are circular on average.

A semiconductor wafer often has a diameter of 300 mm and has several sites, so called dies, each comprising at least one integrated circuit pattern such as for example for a memory chip or for a processor chip. During fabrication, semiconductor wafers run through about 1000 process steps, and, within the semiconductor wafer, about 100 and more parallel layers are formed. The layers comprise transistor layers, the layers of the middle of the line, and the interconnect layers and, in memory devices, a plurality of 3D arrays of memory cells. Dimensions, shapes and placements of the semiconductor structures and patters are typically subject to several influences. Manufacturing of 3D-Memory devices includes etching and deposition. Other process steps, such as the lithography exposure or implantation, also can have an impact on the properties of the IC-elements.

The aspect ratio and the number of layers of integrated circuits constantly increases and the structures are growing into 3^{rd} (vertical) dimension. The current height of the memory stacks exceeds five microns, and in the future may exceed dozens of microns. In contrast, the size of features is smaller. The minimum feature size or critical dimension is below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Therefore, measuring the shape, dimensions and orientation of the features and patterns in 3D and their overlay with high precision can become challenging.

With the increasing demand regarding the resolution of charged particle imaging systems in three dimensions, the inspection and 3D analysis of integrated semiconductor circuits in wafers can become more and more challenging. The lateral measurement resolution of charged particle systems is typically limited by the charged particle beam diameter, sampling raster is adapted accordingly. The sampling raster resolution can be set within the imaging system and can be adapted to the charged particle beam diameter on the sample. The typical raster resolution is 2 nm or below, but the raster resolution limit can generally be reduced with no physical limitation. The charged particle beam diameter has a limited dimension, which depends on the charged particle beam operation conditions and lens. The beam resolution is limited by approximately half of the beam diameter. The resolution can be below 2 nm, for example even below 1 nm.

A common way to generate 3D tomographic data from semiconductor samples on nm scale is the so-called slice and image approach elaborated for example by a dual beam device (DBD). A slice and image approach is described in WO 2020/244795 A1. According to the method of the WO 2020/244795 A1, a 3D volume inspection is obtained at an inspection sample extracted from a semiconductor wafer. In this method, a wafer is destroyed to obtain an inspection sample of block shape. This issue has been addressed by utilizing the slice and image method under a slanted angle into the surface of a semiconductor wafer, as described in WO 2021/180600 A1. According to this method, a 3D volume image of an inspection volume is obtained by slicing and imaging a plurality of cross-section surfaces of the inspection volume. In a first example for a relatively precise measurement, a large number N of cross-section surfaces of the inspection volume is generated, with the number N exceeding 100 or even more image slices. For example, in a volume with a lateral dimension of 5 μm and a slicing distance of 5 nm, 1000 slices are milled and imaged. This method can be relatively time consuming and can involve several hours for one inspection site.

In some inspection tasks, a full 3D volume image is not obtained. The task of the inspection is to determine a set of specific parameters of semiconductor objects such as high aspect ratio (HAR)-structures inside the inspection volume. For determining the set of specific parameters, the number of image slices through a volume can be reduced. WO 2021/180600 A1 illustrates some methods which utilize a reduced number of images slices. In an example, the method applies a priori information. From a single cross-section surface and a 3D volume image of a previous determination step, a property an HAR structures can be derived.

Milling of a wedge with a focused ion beam, FIB, may be affected by a non-planarity of the milled surface. Reference is made to FIG. 1 which shows a sample 10, wherein a focused ion beam 15 in the figure is applied to the upper surface 11 of the sample at an angle α. Because of an interaction of the ions with the surface the FIB beam current decreases with depth, the mill rate decreases with larger z. Depending on the FIB progress rate in direction along the surface, x in FIG. 1 a curved or real surface shape 20 occurs instead of the desired plane surface shape 30 having a wedge angle α. The effects of the non-planarity can be as follows.

In a 3D reconstruction of the sample 10 from a sequence of imaged wedges, distortions can occur if the real surface profile is not considered properly. Horizontal structures may occur non-horizontal or even non-planar in the 3D reconstruction. FIG. 2 shows a 3D NAND structure 40 in which the different surface planes such as a channel start plane 41 the transition plane 42 or the channel termination plane 43 are parallel to each other and to the top surface 45 or bottom surface 46. When a 3D reconstruction is carried out based on the sequence of imaged wedges, reconstruction 50 is obtained in which the corresponding image planes 51, 52 and 53 are not parallel to the surface 55. With increasing height below the surface 55, the distortions increase as can be deduced by comparing the channel termination plane 53 and the channel start plane 51. This can affect the accuracy of the measurements of structures in the depth direction z.

As described in connection with FIG. 3, for reconstructions from single wedges, critical dimension, CD, profiles of 3D NANDs can be falsified. The actual surface is non-planar as indicated by 60 wherein the reconstruction is based on an assumed wedge surface 65 which is a linear surface and not curved. Accordingly with increasing depth the assumed critical dimension or the falsified CD profile 67 does not correspond to the true critical dimension and the true CD profile 66.

It can be desirable to have techniques that can overcome or mitigate at least some of the known restrictions or drawbacks discussed above. For the above discussed reasons, it can be beneficial to know the actual surface shape and to consider the actual surface shape in the derived parameters.

### SUMMARY

In an aspect, the disclosure provides a method for operating a dual beam device, which comprises the steps at the dual beam device of obtaining a milled sample having an assumed milled top surface shape which was obtained by milling the sample with a first ion beam of the dual beam device. Furthermore, a plurality of height coordinates of the assumed milled top surface shape are determined and at least one actual milling top surface shape is determined for the milled sample based on the determined plurality of height coordinates. A parameter of the sample is then determined based on the adapted milled top surface shape.

It is possible to use a second beam of the dual beam device or an optical interferometer, an atomic force microscope or any other measurement device capable of resolving the height profile over a surface. Using the height coordinates of the second beam it is possible to determine the actual height so that the real surface shape and not the assumed straight surface shape is used to determine a parameter such as a three-dimensional position of structures in the sample.

In an aspect, the disclosure provides a system which comprises one or more processing devices and one or more machine-readable hardware storage devices comprising instructions that are executed by the one or more processing devices to perform a method as mentioned above or as discussed in further detail below.

It is to be understood that the features mentioned above and those yet to be explained below may be used not only in the respective combinations indicated, but also in other combinations or in isolation without departing from the scope of the present disclosure.

### BRIEF DESCRIPTION OF THE DRAWINGS

FIG. 1 is a schematic view of a situation where a wedge of a sample is milled using a focused ion beam resulting in a non-planarity of the milled surface.

FIG. 2 provides schematic views of an actual 3D structure and the reconstructed structure based on a milled surface profile which does not correspond to the actual real surface profile.

FIG. 3 shows a schematic view situation where a mismatch occurs between an assumed and a true depth profile.

FIG. 4 schematically illustrates a dual beam system with which an actual surface profile of a milled surface can be determined.

FIG. 5 is an illustration of a method of volume inspection in a wafer with a slanted cross-section milling and imaging by the dial beam device.

FIG. 6 shows two examples of cross section image slices.

FIG. 7 shows an example schematic view of how a focus line along the wedge is used to determine an actual surface profile.

FIG. 8 shows an example schematic representation of how different actual milling top surface shapes are determined at different edge points.

FIG. 9 shows an example schematic representation how a height map obtained at a single position is used for other edge points.

FIG. 10 shows an example schematic representation of how the stationary height profile is used for other edge positions.

FIG. 11 shows an example schematic flowchart of a method carried out by a dual beam device for determining actual milling top surface shapes.

### DETAILED DESCRIPTION

Some examples of the present disclosure generally provide for a plurality of circuits or other electrical devices. All references to the circuits and other electrical devices and the functionality provided by each are not intended to be limited to encompassing only what is illustrated and described herein. While certain labels may be assigned to the various circuits or other electrical devices disclosed, such labels are not intended to limit the scope of operation for the circuits and the other electrical devices. Such circuits and other electrical devices may be combined with each other and/or separated in any manner based on the type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the disclosure will be described in certain detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

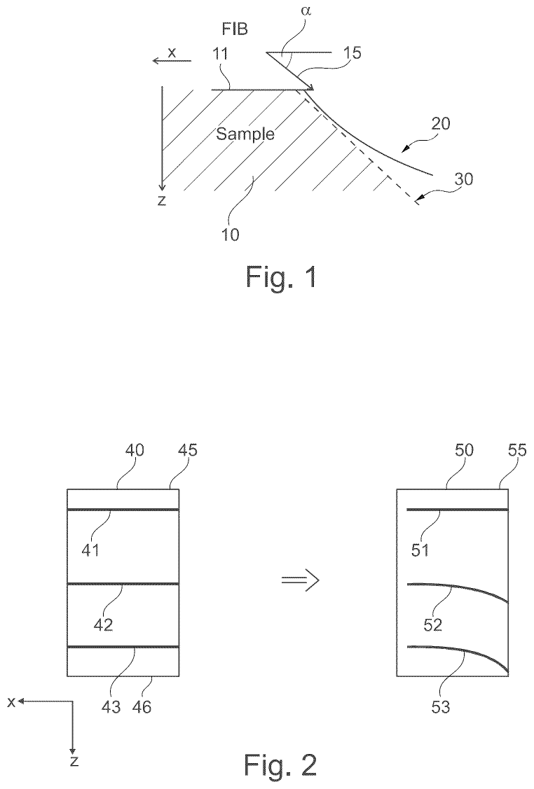

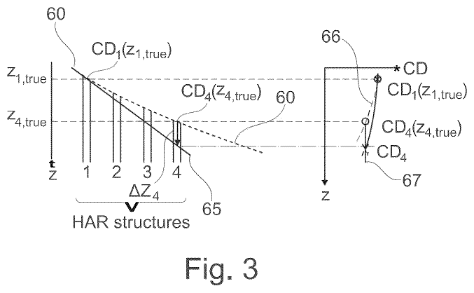

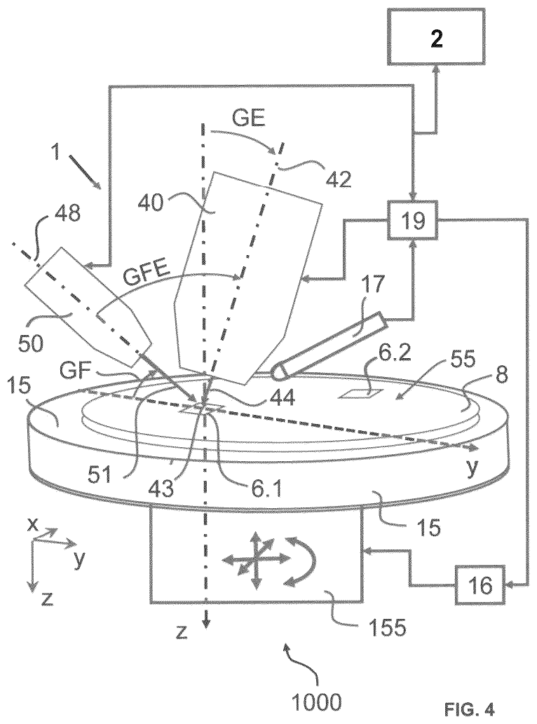

With reference to FIG. 4 a system is shown with which an actual shape of a milled surface is determined. The wafer inspection system 1000 is configured for a slice and imaging method under wedge cut geometry with a dual beam device 1. For a wafer 8, several measurement sites, comprising measurement sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and mechanisms for precision control for a wafer stage such as Laser interferometers are known. A control unit 16 configured to control the wafer stage 155 and to adjust a measurement site 6.1 of the wafer 8 at the intersection point 43 of the dual-beam device 1. The dual beam device 1 is comprising a FIB column 50 with a FIB optical axis 48 and a charged particle beam (CPB) imaging system 40 with optical axis 42. At the intersection point 43 of both optical axes of FIB and CPB imaging system, the wafer surface is arranged at a slant angle GF to the FIB axis 48. FIB axis 48 and CPB imaging system axis 42 include an angle GFE, and the CPB imaging system axis forms an angle GE with normal to the wafer surface 55. In the coordinate system of FIG. 1, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam. With the charged particle beam imaging system 40, inclined under angle GE to the wafer normal, images of the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer at measurement site 6.1, and secondary particles as well as scattered particles are generated. Particle detector 17 collects at least some of the secondary particles and scattered particles and communicates the particle count with a control unit 19. Other detectors for other kinds of interaction products may be present as well. Control unit 19 is in control of the charged particle beam imaging column 40, of FIB column 50 and connected to a control unit 16 to control the position of the wafer mounted on the wafer support table via the wafer stage 155. Control unit 19 communicates with operation control unit 2, which triggers placement and alignment for example of measurement site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM).

In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface.

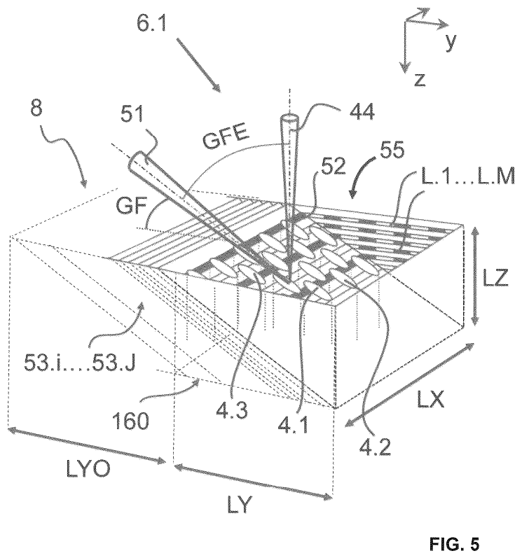

FIG. 5 illustrate further details of the slice and imaging method in the wedge cut geometry. By repetition of the slicing and imaging method in wedge-cut geometry, a plurality of J cross-section image slices comprising image slices of cross-section surfaces 52, 53.i . . . 53.J is generated and a 3D volume image of an inspection volume 160 at an inspection site 6.1 of the wafer 8 at measurement site 6.1 is generated. FIG. 2 illustrates the wedge cut geometry at the example of a 3D-memory stack. The cross-section surfaces 52, 53.1 . . . 53.N are milled with a FIB beam 51 at an angle GF of approximately 30° to the wafer surface 9, but other angles GF, for example between GF=20° and GF=60° are possible as well. FIG. 5 illustrates the situation, when the surface 52 is the new cross-section surface which was milled last by FIB 51. The cross-section surface 52 is scanned for example by SEM beam 44, which is in the example of FIG. 5 arranged at normal incidence to the wafer surface 55, and a high-resolution cross-section image slice is generated. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN— or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 160 nm, for example about 80 nm, or for example 40 nm. The cross-section image slices contain therefore first cross-section image features as intersections or cross-sections of the HAR structure footprints at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44.

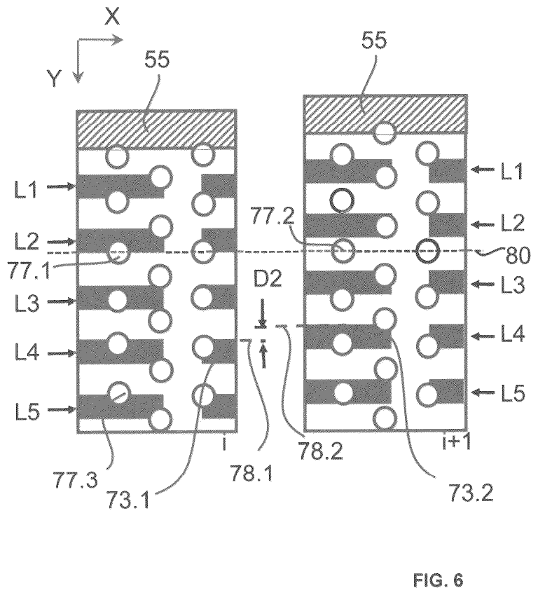

FIG. 6 illustrates an ith and (i+1)-th cross-section image slice at an example. The vertical HAR structures appear in the cross-section image slices as first cross-section image features, for example first cross-section image features 77.1, 77.2 and 77.3. Since the imaging charged particle beam 44 is oriented parallel to the HAR structures, the first cross-section image features representing for example an ideal HAR structures would appear at same y-coordinates. For example, first cross-section image features of ideal HAR structures 77.1 and 77.2 are centered at line 80 with identical Y-coordinate of the ith and (i+1)-th image slice. The cross-section image slices further comprise a plurality of second cross-section image features of a plurality of layers comprising for example layers L1 to L5, for example second cross-section image features 73.1 and 73.2 of layer L4. The layer structure appears as segments of stripes along X-direction in the cross-section image slices. The position of these second cross-section image features representing the plurality of layers, here shown layers L1 to L5, however, changes with each cross-section image slice with respect to the first cross-section image features. As the layers intersect the image planes at increasing depth, the position of the second cross-section image features changes from image slice i to image slice i+1 in a predefined manner. The upper surface of layer L4, indicated by reference numbers 78.1, 78.2, are displaced by distance D2 in y-direction. From determining the positions of the second cross-section image features, for example 78.1 and 78.2, the depth map Z(x,y) of a cross-section image can be determined in case of visible horizontal structures in the sample.

By feature extraction of the second cross-section image features, such as edge detection or centroid computation and image analysis, and according to the assumption of the same or similar depth of the second cross-section image features, the determination of the lateral position as well as the relative depth of the first cross-section image features in cross-section image slices is therefore possible with high precision. Due to the planar fabrication techniques involved in the fabrication of a wafer, layers L1 to L5 are at constant depth over a larger area of a wafer. The depth maps of first cross-section image slices can at least be determined relative the depth of second cross-section images features in the M layers. Further details for the generation of the depth maps ZJ (x,y) for the cross-section image slices are described in WO 2021/180600 A1.

A plurality of J cross-section image slices acquired in this manner covers an inspection volume of the wafer 8 at measurement site 6.1 and is used for forming of a 3D volume image of high 3D resolution below for example 10 nm, such as below 5 nm. The inspection volume 160 (see FIG. 5) typically has a lateral extension of LX=LY=5 μm to 15 μm in x-y plane, and a depth LZ of 2 μm to 15 μm below the wafer surface 55. The full 3D volume image generation according to WO 2021/180600 A1 typically involves milling cross-section surfaces into the surface 55 of the wafer 8 with a larger extension in y-direction as the extension LY. In this example, the additional area with extension LYO is destroyed by the milling of the cross-section surfaces 53.1 to 53.N. In a typical example, the extension LYO exceeds 20 μm.

The operation control unit 2 (see FIG. 4) is configured to perform a 3D inspection inside an inspection volume 160 in a wafer 8. The operation control unit 2 is further configured to reconstruct the properties of semiconductor structures of interest from the 3D volume image. In an example, features and 3D positions of the semiconductor structures of interest, for example the positions of the HAR structures, are detected by the image processing methods, for example from HAR centroids. A 3D volume image generation including image processing methods and feature based alignment is further described in WO 2020/244795 A1, which is hereby incorporated by reference.

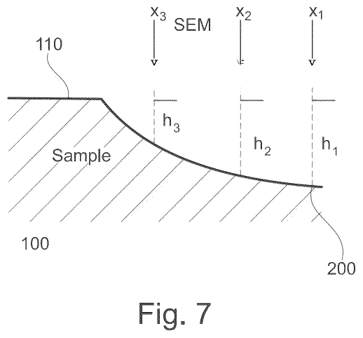

In connection with FIGS. 7 to 11 a solution will be discussed in which a system 1000 as shown in FIG. 4, an FIB-SIM (focused ion beam scanning electron microscope) is used with a focus line down the wedge in order to sample an actual height obtained during a milling process. FIG. 7 shows a schematic view where a sample 100 is shown in a cross-section wherein a milling process such as the one discussed in connection with FIG. 1 has been carried out. The sample 100 can be a wafer such as a wafer 8 shown in FIGS. 4-6. On a top surface 110 of the sample a milling process has been carried out and in order to determine the milling depths at locations x1, x2 or x3 the imaging part such as the imaging part 40 of FIG. 4 is used to generate a focus line along the wedge wherein either the sample 100 is moved below the imaging part or the beam shift is used to move the beam over the surface 110 which may involve a field curvature correction. The focus line and position x1 may result in a height h1, the focus line at position x2 may result in a height h2 and the focus line at position x3 may result in a height h3. With the height the position z along the surface x is known so that it is possible to determine an actual shape of the milling surface 200 which is an actual milling top surface which is not a straight line as the desired surface 30 shown in FIG. 1. The height profile could also have been determined with any other depth measuring device with enough spatial resolution like e.g., interferometer or atomic force microscope.

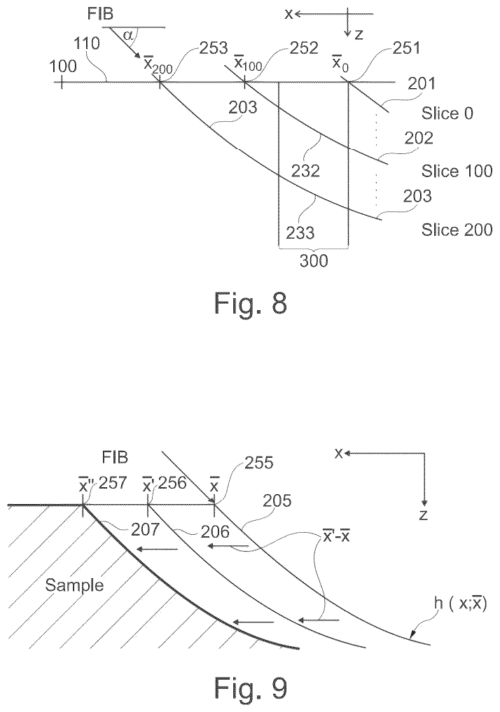

FIG. 8 shows one possible implementation with the collection of height maps during imaging scans. FIG. 8 schematically shows a milling surface 201 belonging to an imaged slice 0 which has an edge point 251 where the ion beam hits the surface 110 of the sample 100. Furthermore, a milled top surface 202 belonging to and imaged slice 100 is shown which has an edge point 252. Furthermore, the milled top surface shape 203 belonging to an imaged slice 200 is shown having an edge point 253 at the surface. The height map collection such as the collection shown in FIG. 7 at each of the slice positions may be too time-consuming, but running a height map measurement, by way of example at every 100 th imaged slice such as a slice 0, 100 and 200 shown in FIG. 8 can be sufficient as the surface profile changes are slow. Furthermore, a region of interest 300 is indicated in which one might be interested to determine a structural feature, such as the features shown in FIGS. 5 and 6, of the sample or its location in the sample. For the correct determination of the spatial position of a feature present in the region of interest 300, the actual milling top surface shape is used for a section of the top surface shape in the example shown in FIG. 8 for section 232 of the top surface shape 202 and the section 233 for the top surface shape 203. If the position x of the intersection of the milled surface with the sample surface, the edge point is known the sample surface can be expanded into a polynomial function along x

$$\begin{matrix}h ( x ; \overline{x} ) = max ( 0 , {a}_{0} ( \overline{x} ) + {a}_{1} ( \overline{x} ) x + … ) \\ with {a}_{0} ( \overline{x} ) = {a}_{00} + {a}_{01} \overline{x} + {a}_{02} {\overline{x}}^{2} + … \\ {a}_{1} ( \overline{x} ) = {a}_{10} + {a}_{11} \overline{x} + {a}_{12} {\overline{x}}^{2} +\end{matrix} \qquad ( 1 )$$

Accordingly, the actual milling top surface h depends on the edge point, wherein in equation (1) it is assumed that the maximum depth is at the surface meaning that the depth has a set value of 0 at the top surface 110 and the values are negative values in the said direction. The coefficients a_{i,j} can be determined from a fit of the measured height maps to the polynomial given in equation 1.

Practically if e.g., the surface shape should be fit to 2^{nd} order in x and the intersection point x dependence to linear order the coefficients a₀₀, a₀₁, a₁₀, a₁₁, a₂₀, a₂₁ are determined. This can be done by measuring the actual surface shape for at least two values of x̅ with at least 3 sampling points x which provides enough information to fit the 6 coefficients.

For a perfect planar mill the coefficients would be

$${a}_{01} = tan ∝ = - {a}_{10}$$

and all other 0.

FIG. 9 shows different milling top surface shapes 205, 206 and 207 for different edge points 255, 256 and 257. It is to be noted that the top surface shapes 205, 206 and 207 may not be identical during the process. However, it can be assumed that after the milling has been started after some milling progress the height profile, i.e. the actual milling top surface shape becomes more or less stationary. In such a stationary milling regime the whole height profile h (x; x̅) is just moved into positive x-direction with the wedge or surface intersection position x. This can mean that it is enough to measure the height profile only once at the end of a run and to project it back to the measured x̅ per slice.

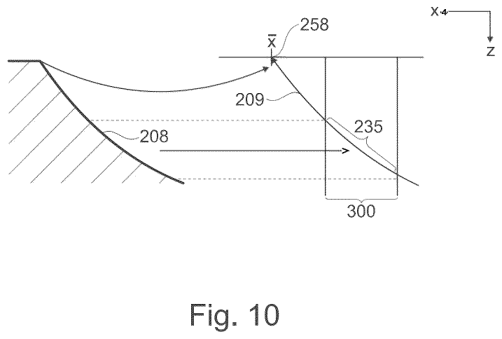

This is reflected by FIG. 10 wherein the stationary and measured height profile 208 is used which is determined at the end of a run of different slices. This stationary height profile is then projected back to the measured edge point 258. Here it is assumed that the top surface shape 209 is the same as the top surface shape 208 and the section 235 may be used to determine a spatial position of any feature of the sample located in the region of interest 300. This means that based on the measured x the stationary profile, the top surface shape is projected back accordingly into the image region of interest and thus a height profile can be assigned for any imaged slice.

Summarizing the present application relates to a method in which a height profile is measured with a focus line (or other devices mentioned before) and the height profile is used to improve the reconstruction by using an actual milling top surface shape.

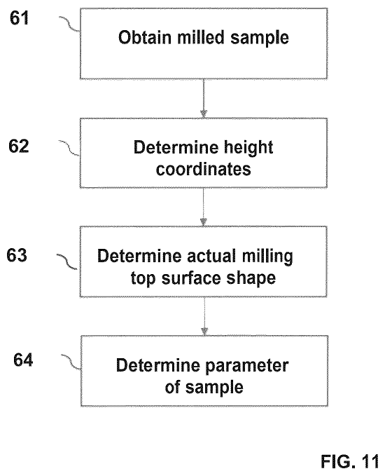

FIG. 11 shows a flowchart of some of the steps carried out during the determination of a structural feature within a milled sample wherein in step S61 a milled sample is obtained either by a milling process or the already milled sample is provided and further examined. The sample has an assumed milled top surface shape wherein the assumed surface shape corresponds to the assumed or desired surface 30 shown in FIG. 1. In step S62 several height coordinates are obtained using the second beam of the dual beam device wherein the height coordinates can be determined using a focus line of the beam (or some other measurement device) that is used to generate tomographic images. In step S63, based on the height coordinates it is possible to determine an actual milling top surface shape such as the surface shapes 201-203, 205-207 or 208, 209 wherein the surface shape is determined using the height coordinates. As discussed above the surface shape can be obtained by a fit of a polynomial equation such as equation 1. When the actual milling top surface shape is known it is possible in step S64 to determine a parameter of the sample such as spatial position of a structural feature in 3-dimensional space so that an improved reconstruction is possible. It is possible to determine localized structural properties of structures in the sample like critical dimension, structure shape, material composition etc. and to place it at the correct spatial position in the reconstruction and thus enabling to draw correct conclusions on the spatial shape and structure of the sample.

From the above said some general conclusions can be drawn. The plurality of height coordinates may be determined with the second beam being substantially perpendicular to the bottom surface of the milled sample or substantially perpendicular to the unmilled top surface of the sample before the milling is carried out or with an optical interferometer or an atomic force microscope or any other height measurement device with suitable spatial and height resolution.

The second beam can be a beam generated by an imaging part of the dual beam device which is configured to obtain the tomographic images of the milled sample at different milled slice positions of the milled sample.

The second beam may be used to obtain the plurality of tomographic images and may be used as a beam for focusing the imaging part on the assumed milled top surface shape.

It is possible that a scan of the height coordinates is not determined for each of the slice positions but for every n-slice position with n>10, >50 or even >95. In the example discussed in connection with FIG. 8 the height coordinates and thus the actual milling top surface shape is determined after 100 slices so that n might be 100. However, it should be understood that any number between 10 or 100 or even 200 might be used.

Each of the at least one actual milling top surface shapes can be described as a polynomial or any other mathematical function such as a set of basis functions along a surface of the milled sample and the coefficients of the mathematical function or basis functions or polynomial are determined from a fit of the plurality of height coordinates to the polynomial. Instead of a polynomial any other function could be used as a basis.

Furthermore, a plurality of actual milling top surface shapes may be determined for a plurality of edge points where the first ion beam hits the top surface of a sample and the fit may be used to determine the adapted top surface shape of an intermediate slice located between two actual milling top surfaces of the plurality of actual milling top surfaces for which the top surface shapes has been calculated.

Furthermore the at least one actual milling top surface shape may be determined at least for an edge point where the first ion beam hits a top surface of the sample.

Here, it is possible to determine one actual milling top surface shape for a single edge point and the actual milling top surface shape at the edge point may be assigned to additional milling top surface shapes starting at other edge points generated during the milling of the sample with the first ion beam.

A section such as sections 232 or 233 of the actual milling top surface shape can be located within a region of interest or slice 300 through the milled sample with the slice being substantially perpendicular to a bottom surface of the milled sample, wherein the spatial position of the at least one structure feature is determined using the section of the actual milling top surface located within the slice.

The plurality of height coordinates for the actual milling top surface may be determined after the last tomographic image has been determined.

Furthermore, it is possible that the actual milling top surface shape is determined for different edge points and the actual milling top surface shapes determined for the different edge points are used to determine the at least one structure feature of the sample.

Summarizing the application describes the use of a height profile with a focus line to determine adapted top milling surfaces wherein these actual milling surfaces or surface shapes can be used to improve reconstructions. Furthermore the above idea could be used together with wedge reconstruction or focus map for sample tilt. The problems mentioned in the introductory part are present for stacks having 10 μm depths or more and these problems will become more severe for deeper stacks such as 50 μm. The above discussed examples were presented as a 2D scheme in the x and z direction, however it should be understood that it can be also used in connection with a 3D environment.

What is claimed is:

1. A method, comprising:
milling a sample using a first beam of a dual beam device to obtain a milled sample comprising a milled surface, the milled surface comprising an assumed surface shape, and the first beam comprising an ion beam;
determining a plurality of height coordinates of the assumed surface shape of the milled surface;
determining an actual surface shape of the milled surface based on the plurality of height coordinates; and
determining a parameter of the sample based on the actual surface shape.

2. The method of claim 1, comprising determining the plurality of height coordinates using a second beam of the dual beam device, wherein the second beam is different from the first beam.

3. The method of claim 2, wherein the second beam is substantially perpendicular to a surface of the milled sample that is opposite to the milled surface.

4. The method of claim 2, comprising generating the second beam using an imaging part of the dual beam device.

5. The method of claim 2, comprising obtaining tomographic images of the milled sample using the second beam.

6. The method of claim 5, comprising, after obtaining the tomographic images, determining the plurality of height coordinates.

7. The method of claim 5, comprising determining the plurality of height coordinates based on a focus line of the imaging part present when taking the tomographic images.

8. The method of claim 1, comprising determining the plurality of height coordinates at more than 10 positions of the assumed surface shape.

9. The method of claim 1, comprising describing the actual surface shape as an expansion into a set of basis functions along a surface of the milled sample, and determining coefficients of the set of basis functions based on a fit of the plurality of height coordinates to the set of basis functions.

10. The method of claim 9, comprising:
for each of a plurality of surfaces of the milled sample, determining an actual surface shape at an edge point where the first beam hit the surface of the sample; and
using the fit to determine an adapted surface shape of an intermediate slice located between two of the actual surface shapes.

11. The method of claim 1, comprising determining the actual surface shape for an edge point where the first beam hit the surface of the sample.

12. The method of claim 11, comprising determining the actual surface shape at a single edge point, and assigning the surface shape at the single edge point to additional surface shapes starting at other edge points generated while milling the sample using the first beam.

13. The method of claim 11, comprising:
for each of a plurality of actual surface shapes, determining the actual surface shape at different edge points of the surface; and
using the actual surface shapes to determine the parameter of the sample.

14. The method of claim 1, wherein a section of the actual surface shape is located within a slice through the milled sample, the slice is substantially perpendicular to a surface of the milled sample that is opposite to the milled surface, and the parameter is determined using the section of the actual surface shape located within the slice.

15. The method of claim 1, wherein determining the parameter comprises determining a spatial position of a structural feature of the sample based on the actual surface shape.

16. The method of claim 1, comprising using a second beam of the dual beam device to determine the plurality of height coordinates, wherein the second beam is different from the first beam.

17. The method of claim 16, wherein the second beam comprises an electron beam.

18. One or more machine-readable hardware storage devices comprising instructions that are executable by one or more processing device to perform operations comprising the method of claim 1.

19. A system, comprising:
one or more processing devices; and
one or more machine-readable hardware storage devices comprising instructions that are executable by one or more processing device to perform operations comprising the method of claim 1.

20. The system of claim 19, further comprising the dual beam device.
